(19) United States
(12) Patent Application Publication
(10) Pub. No.: US 2005/0277226 A1
(43) Pub. Date: Dec. 15, 2005

(54) High density flip chip interconnections

(76) Inventors: Yinon Degani, Highland Park, NJ (US); Jericho J. Jacala, North Plainfield, NJ (US)

Correspondence Address: David P. Kelley, 3822 Courtyard Drive, Atlanta, GA, 30339, US

(21) Appl. No.: 10/856,269

(22) Filed: May 28, 2004

(51) Int. Cl. H01L 21/44

(52) U.S. Cl. 438/108

(57) ABSTRACT

A printed circuit board has, on one surface thereof, a plurality of metallic pads forming or leading to wire traces. The printed circuit board surface is solder mask free and a substantially runless soldering alloy is used to connect I/O solder bumps on a flip chip to the metallic pads.

### FIELD OF THE INVENTION

This application is related to printed circuit boards (PCB) having an integrated circuit chip or chips affixed thereto, and, more particularly, to a PCB having a flip chip affixed thereto.

### BACKGROUND OF THE INVENTION

As the printed circuit art becomes more and more complex, and as smaller and smaller footprints are desired or required, the use of flip chips, which lend themselves to miniaturization, i.e., smaller footprint, and which enable the use of more complex circuitry for interconnection therewith, in becoming more and more in demand and, consequently, more popular. In a typical flip chip arrangement, the flip chip having a plurality of input/output (I/O) solder bumps thereon is attached to metal pads, usually copper pads, on the printed circuit board by soldering it thereto. The procedure requires the use of a solder mask or masks to prevent intrusion of the molten solder onto the metal traces of the PCB, which would otherwise render such circuit traces invalid or inoperable by inevitably short circuiting the traces.

As the number of I/O bumps increases in density PCBs and the dimensions of the PCB and the flip chip decreases, there is a growing need for PCBs having higher and higher densities, resulting in finer and finer pitches between the metal pads on the PCB, which are limited by the presence of solder masks.

One problem that arises with decreased size, more coupled circuitry, and higher circuit densities arises from the solder itself. Eutectic tin-lead solder, which is the universally used solder in the manufacture of PCBs, has a tendency to run when being applied, and often to run over the exposed metal parts of the PCB. This tendency is typical of lead bearing solders. As a consequence of the running characteristic it is necessary to use solder masks on the PCB when soldering the flip chip thereto. It can readily be appreciated that the use of solder masks, which occupy a portion of the available space, creates a physical limit to the minimum dimensions of the assembly that can be achieved, and to the maximizing of density.

### SUMMARY OF THE INVENTION

The present invention is based upon the use of lead-free solder in the fabrication of PCB assemblies. It has been found that certain lead-free solders, such as tin-silver or tin-silver-copper do not have the tendency to run or wet forward aggressively on copper or certain other metal surfaces as in the manner of lead containing solder, yet such solders form reliable metallic bonds with the copper traces. It is not necessary, therefore, to use solder masks to block or prevent running, and thus that particular limitation toward miniaturization and maximizing density is removed.

In an illustrative embodiment of the invention, a solder mask free printed circuit board has, thereon a plurality of metal pads, preferably of copper, forming the metal traces of the PCB, and there is no solder mask or masks separating them and shielding them from running solder. As a consequence, the pitch, i.e., the distance between adjacent metal pads, can be greatly reduced, thereby allowing a more compact PCB with the possibility of greater complexity of circuitry and greater density thereof. The solder used to join the flip chip to the PCB is a lead-free solder, preferably of a tin-silver alloy, which has a minimal or non-existent tendency to run between adjacent the metal pads or traces.

The various features and principles of the present invention will be more readily apparent from the following detailed description, read in conjunction with the accompanying drawings.

### BRIEF DESCRIPTION OF THE DRAWINGS

In the drawings hereinafter, the several arrangements depicted therein are not drawn to scale, several elements having exaggerated dimensions relative to other elements, and in all cases are intended as diagrammatic representations of the actual apparatus.

FIG. 1 is a side elevation view of a PCB and flip chip prior art assembly;

FIG. 2 is a side elevation view of a PCB illustrating the pitch between components on its surface;

FIG. 3 is a side elevation view of PCB structurally similar to that of FIG. 1 and including an illustration of the pitch;

FIG. 4 is a side elevation view of the PCB of the present invention to which a flip chip (not shown) is to be attached; and

FIG. 5 is a side elevation view of the PCB assembly of the present invention with the flip chip soldered in place.

### DETAILED DESCRIPTION

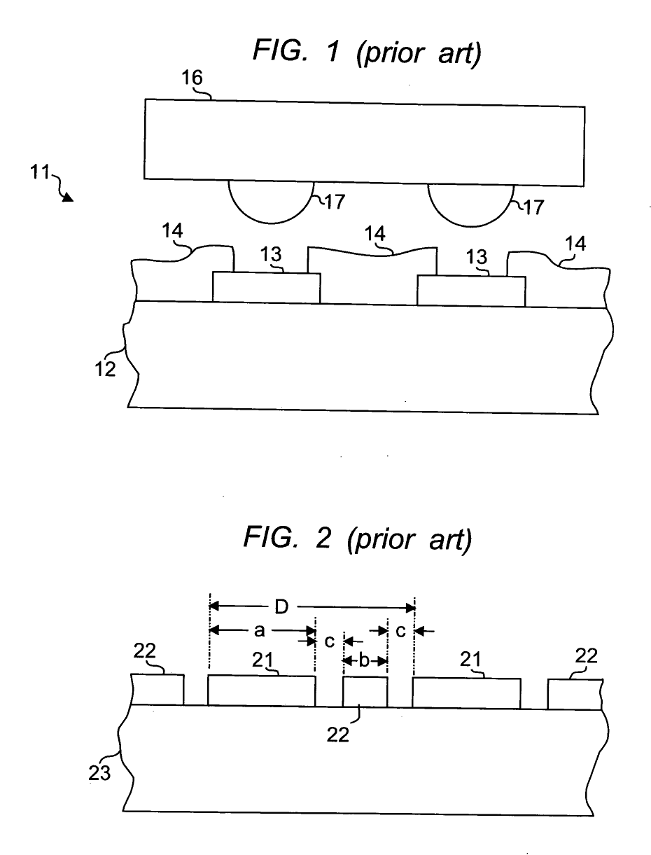

The assembly 11 of FIG. 1, which is characteristic of present day practice, comprises a printed circuit board 12 having a plurality of copper or other conductive metal pads 13 which form the circuit traces. Separating the pads 13 are solder masks 14 which prevent the solder to be used when the flip chip 16 is attached to the circuit board from running between pads, thereby shorting them. In the attaching of the flip chip to the printed circuit board, I/O bumps 17 are soldered to, or connect with the pads 13. It can be seen that the mask or masks 14 form barriers against any tendency of the solder to run beyond the restricted top surfaces of the pads 13. However, as pointed out hereinbefore, the masks form an impediment to miniaturization and/or increased density.

In FIG. 2 there is shown one type of solder masked printed circuit board common in the prior art, illustrating the minimal pitch between adjacent pads 21 having solder masks 22 interposed therebetween and mounted on a printed circuit board 23. The minimal pitch D between two adjacent metal pads, which, at least to some extent is dictated by the PCB process manufacturing tolerances, is equal to the sum of the width “a” of one of the pads 21, plus the minimum solder mask width “b” plus twice the minimum solder mask tolerance “c”. For example, where “a” equals 75 microns, “b” equals 50 microns; and “c” is the solder mask tolerance and equals 50 microns, then the pitch D is given by
D=a+b+2c=75μ+50μ+100μ=225μ (1)
which represents the minimum feasible dimensions where, for example, lead based solder is used.

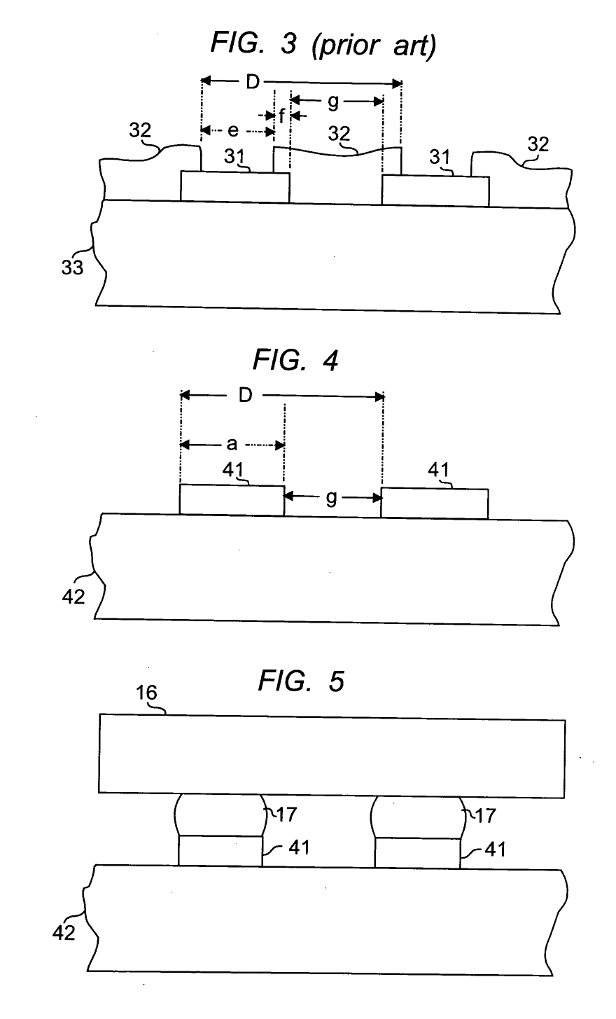

FIG. 3 depicts to pitch parameters for the PCB of FIG. 1. In this embodiment of prior art practice, it can be seen that the solder masks 32 overlie the ends of the copper pads 31 a distance “f”. Thus the minimum distance D between adjacent metal pads becomes
D=e+2f+g=75μ+2×50 μ+50μ=225μ (2)
where c is the minimum distance between two metal pads.
From the foregoing, it can be seen that the pitch is, to a large extent, determined by the amount of space occupied by the masks, which places a lower limit on miniaturization and a concomitant upper limit upon the density of circuitry on the PCB. While 225μ is not intended to represent an absolute minimum pitch, it does represent a practical limit on the lower value of pitch and, hence, of any further increase in the circuit density.

An illustrative embodiment of the invention is shown in FIG. 4, wherein the PCB 42 has affixed thereon a plurality (shown as two) metal pads 41, having a width “a” and separated by a distance “g”. The part of the assembly shown is maskless, inasmuch as a lead based solder is not being used but, rather, a solder having a substantially runless characteristic such as, for example, a tin-silver alloy, or a tin-silver-copper alloy is being used, thereby obviating the necessity for masking. When the solder masks are eliminated, the pad to pad distance can be reduced to the minimum metal to metal distance “g”, where g is equal to 50 microns. Thus, the minimum distance D between adjacent metal pads becomes
D=a+g=75μ+50μ=125μ (3)
where g is the minimum distance between two metal pads.

It is clear, from this, that density of the circuitry on the PCB can be nearly doubled over that of present day PCB assemblies. Further, even with an increase in density, there can be, too, an increase in miniaturization inasmuch as the invention clearly makes possible the need for less space on the PCB for a given circuit pattern or traces.

FIG. 5 is a side elevation view of the completed assembly, with the flip chip 16 soldered in place upon the PCB of FIG. 4 by means of the lead free solder 17.

The foregoing has been illustrative of the present invention in an illustrative embodiment thereof. These principles and features may be readily applied to other arrangements not herein disclosed that may occur to workers in the art, without departure from the spirit and scope of the invention.

1. A high density flip chip interconnection assembly comprising:
a printed circuit board;
a plurality of metallic pads mounted on a surface of said board;
a flip chip member soldered to said metallic pads; and
said printed circuit board being free of solder masks in the area of the said metal pads on said surface beneath said flip chip member.

2. A high density flip chip interconnection assembly as claimed in claim 1 wherein the solder for soldering the flip chip to said printed circuit board comprises a solder material having a substantially runless characteristic when soldered to said metallic pads.

3. A high density flip chip interconnection assembly as claimed in claim 2 wherein said solder is lead free.

4. A high density flip chip interconnection assembly as claimed in claim 3 wherein said solder material is a tin-silver alloy.

5. A high density flip chip interconnection assembly as claimed in claim 3 wherein said solder material is a tin-silver-copper alloy.

6. A high density flip chip interconnection assembly as claimed in claim 2 wherein said metallic pads use copper and/or copper alloy metallurgy.

7. For use in a high density flip chip interconnection assembly,
a printed circuit board having a plurality of metallic pads on a surface thereof to which the flip chip is to be connected by a substantially runless solder;
said surface being devoid of solder masks;
said pads having a pitch given by
D=a+c
where “a” is the width of one of said pads and “c” is the spacing between adjacent pads.

8. The printed circuit board as claimed in claim 7 wherein the pitch D is less than approximately 225 microns.
